(19) United States
(12) Patent Application Publication
(10) Pub. No.: US 2025/0359279 A1
(43) Pub. Date: Nov. 20, 2025

(54) SEMICONDUCTOR DEVICE AND METHOD OF FABRICATING THE SAME

(71) Applicant: Samsung Electronics Co., Ltd., Suwon-si (KR)

(72) Inventors: Junsoo Kim, Suwon-si (KR); Gyul Go, Suwon-si (KR); Dongsik Kong, Suwon-si (KR); Jeonghoon Oh, Suwon-si (KR); Sungho Jang, Suwon-si (KR)

(21) Appl. No.: 18/940,992

(22) Filed: Nov. 8, 2024

(30) Foreign Application Priority Data
May 17, 2024 (KR) 10-2024-0064304

(51) Int. Cl. H01L 29/49; H10B 12/00

(52) U.S. Cl. CPC H10D 64/66; H10B 12/315; H10B 12/482

(57) ABSTRACT

A semiconductor device may include a substrate, a bit line extending in a first direction parallel to a top surface of the substrate, a semiconductor pattern on the bit line and extending in a third direction perpendicular to the top surface of the substrate, and a gate electrode on a side surface of the semiconductor pattern and extending in a second direction parallel to the top surface of the substrate and intersecting the first direction. The gate electrode may include a work function adjusting material, and a first atomic concentration of the work function adjusting material in each of lower and upper portions of the gate electrode may be higher than a second atomic concentration of the work function adjusting material in a center portion of the gate electrode between the lower and upper portions.

### CROSS-REFERENCE TO RELATED APPLICATIONS

This U.S. non-provisional patent application claims priority under 35 U.S.C. § 119 to Korean Patent Application No. 10-2024-0064304, filed on May 17, 2024, in the Korean Intellectual Property Office, the entire contents of which are hereby incorporated by reference.

### BACKGROUND

The present disclosure relates generally to a semiconductor device, and in particular, to a semiconductor device and a method of fabricating the same.

Due to their small-sized, multifunctional, and/or low-cost characteristics, semiconductor devices are being esteemed as important elements in the electronic industry. The semiconductor devices are classified into a semiconductor memory device for storing data, a semiconductor logic device for processing data, and a hybrid semiconductor device including both memory and logic elements.

Due to the recent increasing demand for electronic devices with a fast speed and/or low power consumption, the semiconductor device requires a fast operating speed and/or a low operating voltage. To satisfy these requirements, it is necessary to increase an integration density of the semiconductor device. Thus, many studies are being conducted to realize a highly-integrated semiconductor device.

### SUMMARY

An embodiment of the inventive concept provides a semiconductor device with an increased productivity and a method of fabricating the same.

An embodiment of the inventive concept provides a semiconductor device with improved electrical and reliability characteristics and a method of fabricating the same.

According to an embodiment of the inventive concept, a semiconductor device may include a substrate, a bit line extending in a first direction parallel to a top surface of the substrate, a semiconductor pattern provided on the bit line and extending in a third direction perpendicular to the top surface of the substrate, and a gate electrode provided on a side surface of the semiconductor pattern and extending in a second direction parallel to the top surface of the substrate and intersecting the first direction. The gate electrode may include a work function adjusting material, and an atomic concentration of the work function adjusting material in each of lower and upper portions of the gate electrode may be higher than an atomic concentration of the work function adjusting material in a center portion of the gate electrode between the lower and upper portions.

According to an embodiment of the inventive concept, a semiconductor device may include a substrate, a bit line extending in a first direction parallel to a top surface of the substrate, a semiconductor pattern provided on the bit line and extending in a third direction perpendicular to the top surface of the substrate, and a gate electrode provided on a side surface of the semiconductor pattern and extending in a second direction parallel to the top surface of the substrate and intersecting the first direction. Each of lower and upper portions of the gate electrode may include a work function adjusting material, and a work function of each of the lower and upper portions of the gate electrode may be smaller than a work function of a center portion of the gate electrode between the lower and upper portions.

According to an embodiment of the inventive concept, a semiconductor device may include a substrate, a bit line extending in a first direction parallel to a top surface of the substrate, a semiconductor pattern provided on the bit line and extending in a third direction perpendicular to the top surface of the substrate, the semiconductor pattern including a first edge portion adjacent to the bit line and a second edge portion opposite to the first edge portion, a bit line contact between the first edge portion of the semiconductor pattern and the bit line, a gate electrode provided on a side surface of the semiconductor pattern and extending in a second direction parallel to the top surface of the substrate and intersecting the first direction, a storage node contact on the second edge portion of the semiconductor pattern, a landing pad on the storage node contact, and a data storage pattern on the landing pad. The gate electrode may include a work function adjusting material, an atomic concentration of the work function adjusting material in each of lower and upper portions of the gate electrode may be higher than an atomic concentration of the work function adjusting material in a center portion of the gate electrode between the lower and upper portions.

According to an embodiment of the inventive concept, a method of fabricating a semiconductor device may include forming a semiconductor pattern on a first substrate to extend in a direction perpendicular to a top surface of the first substrate, forming a gate electrode on a side surface of the semiconductor pattern to extend in a direction parallel to the top surface of the first substrate, performing a first doping process on a first portion of the gate electrode, flipping the first substrate, and performing a second doping process on a second portion of the gate electrode. Each of the first and second doping processes may include injecting a work function adjusting material into the gate electrode.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1 is a block diagram illustrating a semiconductor device according to an embodiment of the inventive concept;

FIGS. 2 and 3 are perspective views schematically illustrating a semiconductor device according to an embodiment of the inventive concept;

FIG. 4 is a schematic plan view illustrating a semiconductor device according to an embodiment of the inventive concept;

FIG. 5 is a schematic cross-sectional view taken along line A-A′ of FIG. 4;

FIG. 6A is an enlarged schematic cross-sectional view corresponding to a region ‘P1’ of FIG. 5;

FIGS. 6B and 6C are graphs illustrating an atomic concentration of a work function adjusting material as a function of a height of a gate electrode of a semiconductor device, according to an embodiment of the inventive concept;

FIG. 7A is an enlarged schematic cross-sectional view corresponding to a region ‘P2’ of FIG. 5;

FIGS. 7B and 7C are graphs illustrating an atomic concentration of a work function adjusting material as a function of a height of a back-gate electrode of a semiconductor device, according to an embodiment of the inventive concept; and

FIGS. 8 to 11 are schematic cross-sectional views illustrating intermediate processes in an example method of fabricating a semiconductor device according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their descriptions will not be repeated.

It will be understood that although ordinal terms, such as first, second, etc., may be used herein to describe various elements and/or process steps, these elements and/or process steps should not be limited by such terms. Rather, these terms are merely used to distinguish one element and/or step from another and may not necessarily be used to convey any particular order of the elements and/or steps unless expressly noted.

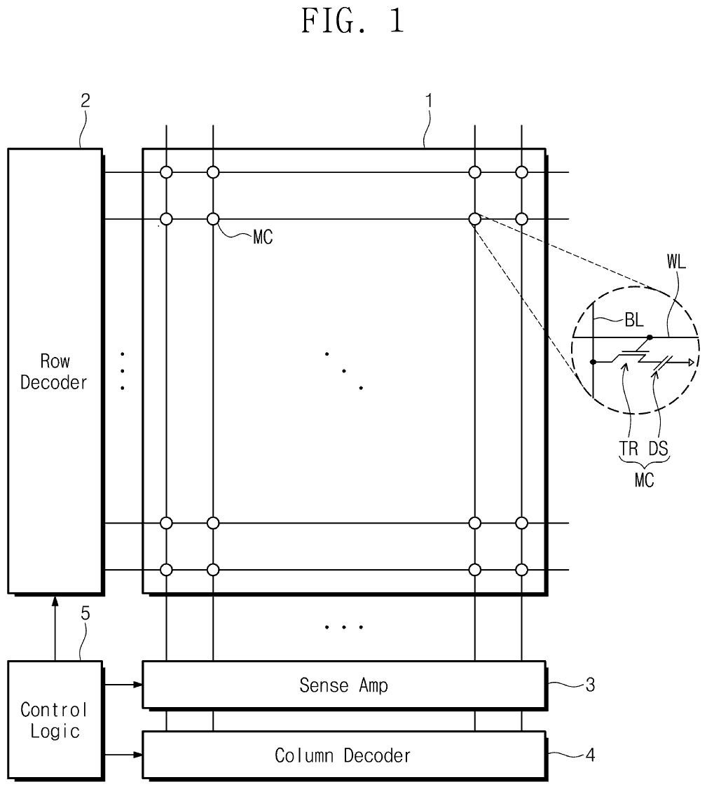

FIG. 1 is a block diagram illustrating a semiconductor device according to an embodiment of the inventive concept.

Referring to FIG. 1, a semiconductor device may include a memory cell array 1, a row decoder 2, a sense amplifier 3, a column decoder 4, and a control logic 5.

The memory cell array 1 may include a plurality of memory cells MC, which are two- or three-dimensionally arranged. Each of the memory cells MC may be provided between and connected to a corresponding word line WL and a corresponding bit line BL, which are provided to cross each other. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. Each of the memory cells MC may include a selection element TR and a data storing element DS. The selection element TR and the data storing element DS may be electrically connected to each other. The selection element TR may be connected to both the word line WL and the bit line BL. In other words, the selection element TR in each of the memory cells MC may be provided at an intersection of the corresponding word and bit lines WL and BL.

The selection element TR may include a field effect transistor. The data storing element DS may include, for example, a capacitor, a magnetic tunnel junction pattern, or a variable resistor. As an example, the selection element TR may be a transistor whose gate, source, and drain terminals are connected to the word line WL, the bit line BL, and the data storing element DS, respectively.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may be configured to construct a data transmission path between the sense amplifier 3 and an external device (e.g., memory controller). The column decoder 4 may be configured to decode address information, which is input from the outside, and to select one of the bit lines BL, based on the decoded address information. The control logic 5 may generate control signals, which are used to control an operation of writing or reading data to or from the memory cell array 1.

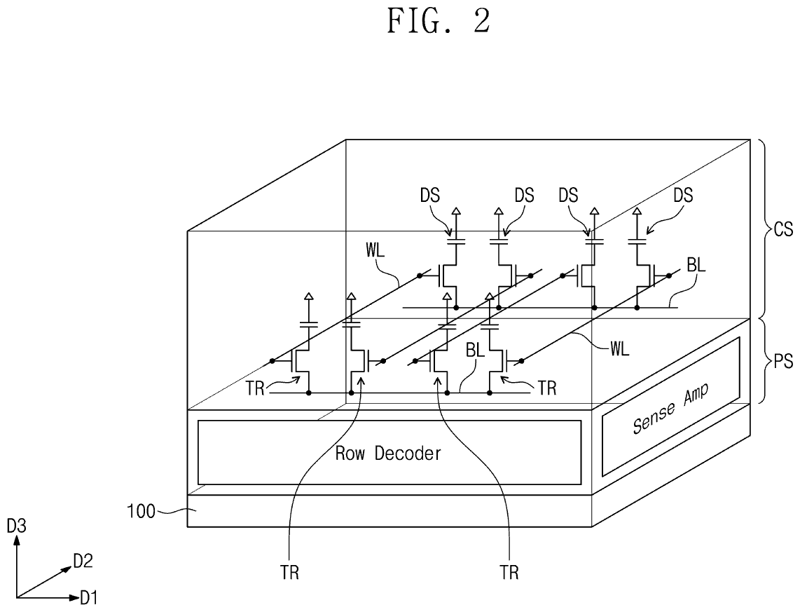

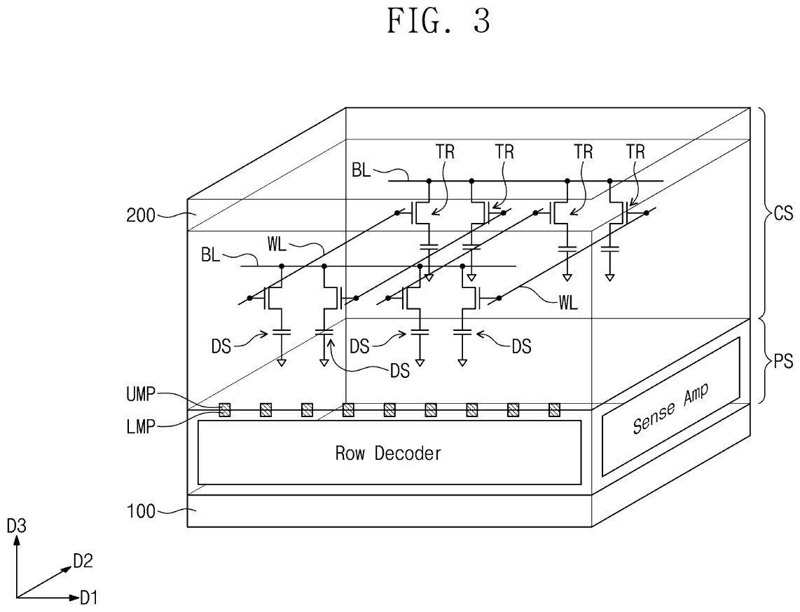

FIGS. 2 and 3 are perspective views schematically illustrating a semiconductor device according to an embodiment of the inventive concept.

Referring to FIGS. 2 and 3, the semiconductor device may include a peripheral circuit structure PS on a substrate 100 and a cell array structure CS connected to the peripheral circuit structure PS. The substrate 100 may be a plate-shaped structure that extends parallel to a plane defined by a first direction D1 and a second direction D2. The first and second directions D1 and D2 may be parallel to a top surface of the substrate 100 and may not be parallel to each other. A third direction D3 may be perpendicular to the top surface of the substrate 100 and may not be parallel to the first and second directions D1 and D2.

The peripheral circuit structure PS may include core and peripheral circuits formed on the substrate 100. The core and peripheral circuits may include the row and column decoders 2 and 4, the sense amplifier 3, and the control logics 5 described with reference to FIG. 1.

The cell array structure CS may include the memory cell array 1 (e.g., of FIG. 1), in which the memory cells MC (e.g., of FIG. 1) are two-dimensionally or three-dimensionally arranged. In an embodiment, the selection element TR of each of the memory cells MC of FIG. 1 may include a vertical channel transistor (VCT). The vertical channel transistor may include a channel pattern that extends parallel to the third direction D3.

Referring to FIG. 2, the peripheral circuit structure PS may be provided on the substrate 100. The cell array structure CS may be provided on the peripheral circuit structure PS. Although not illustrated, the peripheral circuit structure PS may be connected to the cell array structure CS through an additional contact.

Referring to FIG. 3, the semiconductor device may have a chip-to-chip (C2C) structure. The peripheral circuit structure PS may be provided on the substrate 100. First metal pads LMP may be provided in an upper portion of the peripheral circuit structure PS. The first metal pads LMP may be electrically connected to the core and peripheral circuits. The first metal pads LMP in the peripheral circuit structure PS may be electrically contacted (e.g., bonded) to second metal pads UMP of the cell array structure CS, which will be described below. Thus, the peripheral circuit structure PS may be bonded to the cell array structure CS.

The cell array structure CS may be provided on a carrier substrate 200. The second metal pads UMP may be provided in a lower portion of the cell array structure CS. The second metal pads UMP may be electrically connected to the memory cell array 1 of FIG. 1.

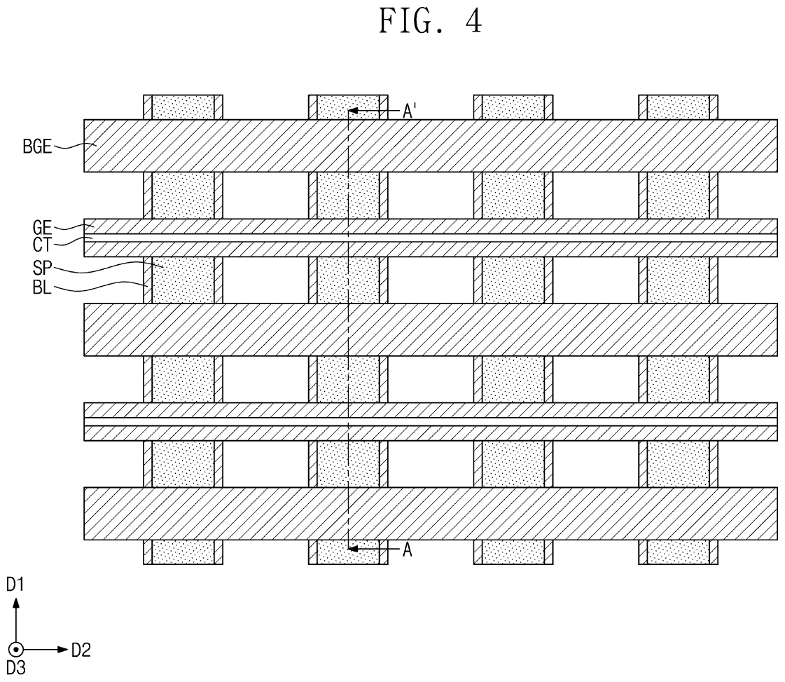

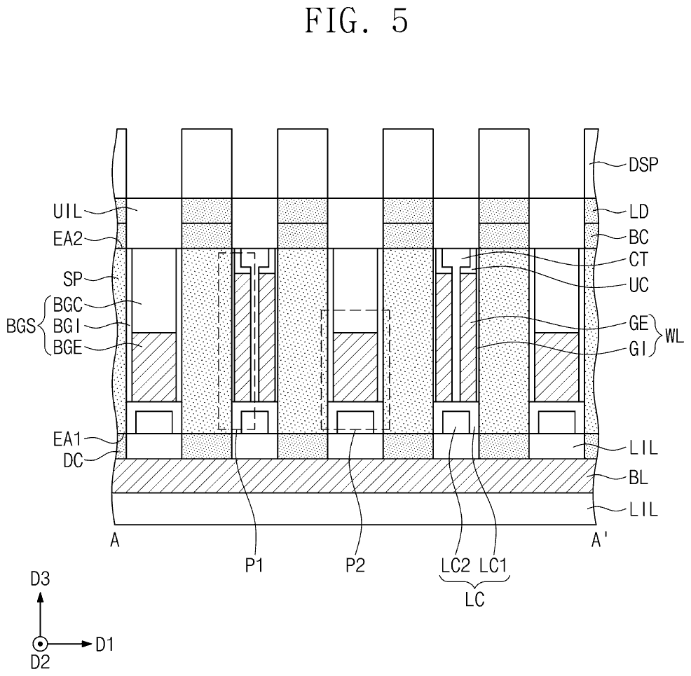

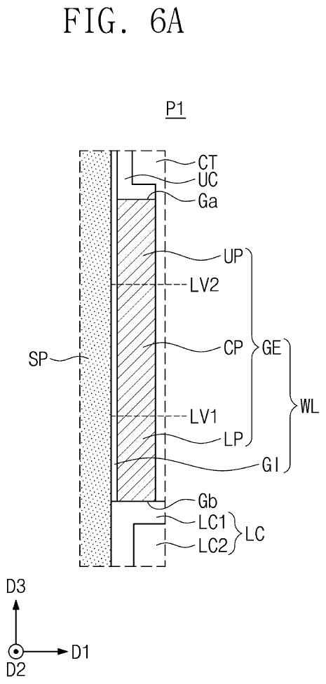

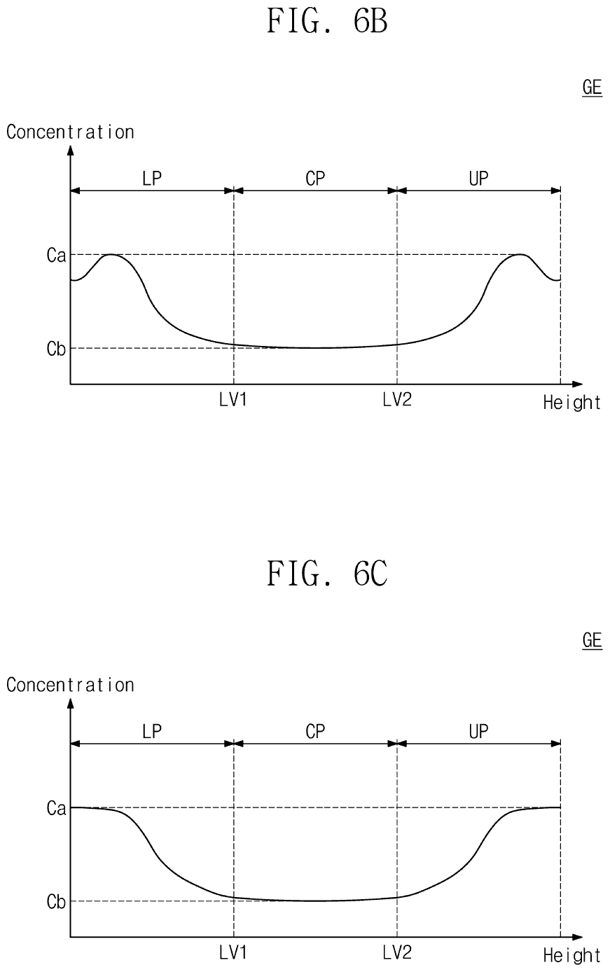

FIG. 4 is a schematic plan view illustrating a semiconductor device according to an embodiment of the inventive concept. FIG. 5 is a schematic cross-sectional view taken along a line A-A′ of FIG. 4. FIG. 6A is an enlarged schematic cross-sectional view corresponding to a region ‘P1’ of FIG. 5. FIGS. 6B and 6C are graphs illustrating an atomic concentration of a work function adjusting material as a function of a height of a gate electrode of a semiconductor device, according to an embodiment of the inventive concept.

In detail, FIGS. 4 and 5 are plan and cross-sectional views, respectively, which illustrate elements in the cell array structure CS described with reference to FIGS. 2 and 3.

The semiconductor device may include a lower insulating layer LIL. The lower insulating layer LIL may include an insulating material. In an embodiment, the lower insulating layer LIL may be provided in a lower portion of the cell array structure CS described with reference to FIG. 2. Here, the lower insulating layer LIL may be adjacent to and in contact with the peripheral circuit structure PS described with reference to FIG. 2. In addition, the peripheral circuit structure PS of FIG. 2 may be interposed between the substrate 100 and the lower insulating layer LIL described with reference to FIG. 2. In addition, interconnection lines that are connected to the core and peripheral circuits of the peripheral circuit structure PS described with reference to FIG. 2 are disposed in the lower insulating layer LIL.

As another example, the cell array structure CS (e.g., see FIG. 2) of the semiconductor device may be flipped (in the third direction D3, or upside down) such that the lower insulating layer LIL is provided in an upper portion of the cell array structure CS described with reference to FIG. 3. Here, the lower insulating layer LIL may be adjacent to and in contact with the carrier substrate 200 described with reference to FIG. 3. The semiconductor device is described with reference to FIGS. 4 and 5 illustrating the cell array structure CS (e.g., see FIG. 2) in a non-inverted state, but the inventive concept is not limited to this example.

The bit line BL may be provided in the lower insulating layer LIL. The bit line BL in the lower insulating layer LIL may extend in the first direction D1. The bit line BL may include a conductive material. In an embodiment, the bit line BL may be formed of or include at least one of doped semiconductor materials (e.g., doped silicon and doped germanium), metallic materials (e.g., Ti, Mo, W, Cu, Al, Ta, Ru, Ir, and Co), metal silicide materials (e.g., silicide materials containing Ti, Mo, W, Cu, Al, Ta, Ru, Ir, and Co), or metal nitride materials (e.g., nitride materials containing Ti, Mo, W, Cu, Al, Ta, Ru, Ir, and Co), although embodiments are not limited thereto. The bit line BL may include a single layer or a composite layer. In an embodiment, a plurality of bit lines BL may be provided. The bit lines BL may be spaced apart from each other in the second direction D2.

A bit line contact DC may be provided in the lower insulating layer LIL. The bit line contact DC may be provided on the bit line BL. The bit line contact DC may be interposed between a semiconductor pattern SP, which will be described below, and the bit line BL. Thus, the bit line BL may be connected to the semiconductor pattern SP through the bit line contact DC. The bit line contact DC may include a conductive material. In an embodiment, the bit line contact DC may be formed of or include doped silicon. In an embodiment, a plurality of bit line contacts DC may be provided. The bit line contacts DC on the bit line BL may be spaced apart from each other in the first direction D1.

The semiconductor pattern SP may be provided on the bit line BL. In an embodiment, the semiconductor pattern SP may be provided on a top surface of the bit line contact DC. The semiconductor pattern SP on the bit line BL may extend in the third direction D3. In an embodiment, a plurality of semiconductor patterns SP may be provided. The semiconductor patterns SP on each bit line BL may be spaced apart from each other in the first direction D1. The semiconductor patterns SP may be spaced apart from each other in the second direction D2.

The semiconductor pattern SP may include a semiconductor material. In an embodiment, the semiconductor pattern SP may be formed of or include at least one of silicon (e.g., single crystalline silicon), germanium, or silicon-germanium. In an embodiment, the semiconductor pattern SP may be formed of or include an oxide semiconductor material. Here, the oxide semiconductor material may include at least one of InGaZnO, InGaSiO, InSnZnO, InZnO, ZnO, ZnSnO, ZnON, ZrZnSnO, SnO, HfInZnO, GaZnSnO, AlZnSnO, YbGaZnO, or InGaO, but the inventive concept is not limited to this example. In an embodiment, the semiconductor pattern SP may include indium gallium zinc oxide (IGZO). In an embodiment, the semiconductor pattern SP may include a two-dimensional semiconductor material. Here, the two-dimensional semiconductor material may include, for example, graphene, carbon nanotube, or combinations thereof.

The word line WL may be provided on a side surface of the semiconductor pattern SP. The word line WL may be interposed between the semiconductor patterns SP, which are adjacent to each other in the first direction D1. The word line WL may extend in the second direction D2. In an embodiment, a plurality of word lines WL may be provided. The word lines WL may be spaced apart from each other in the first direction D1. In an embodiment, a pair of word lines WL, which are adjacent to each other in the first direction D1, may be interposed between the semiconductor patterns SP, which are adjacent to each other in the first direction D1. In an embodiment, a pair of word lines WL, which are adjacent to each other in the first direction D1, may be spaced apart from each other, and a cutting pattern CT may be interposed therebetween, as will be described below.

The word line WL may include a gate electrode GE, which extends in the second and third directions D2 and D3, and a gate insulating pattern GI, which is provided between the semiconductor pattern SP and the gate electrode GE. The gate electrode GE may include a conductive material. In an embodiment, the gate electrode GE may be composed of a single layer. In an embodiment, the gate electrode GE may be formed of or include at least one of metallic materials (e.g., Ti, Mo, W, Cu, Al, Ta, Ru, Ir, and Co), metal silicide materials (e.g., silicide materials containing Ti, Mo, W, Cu, Al, Ta, Ru, Ir, and Co), or metal nitride materials (e.g., nitride materials containing Ti, Mo, W, Cu, Al, Ta, Ru, Ir, and Co), although embodiments are not limited thereto. In an embodiment, the gate insulating pattern GI may be formed of or include at least one of silicon oxide or high-k dielectric materials. In the present specification, the high-k dielectric material may be defined as a material whose dielectric constant is higher than a dielectric constant of silicon oxide.

Referring to FIGS. 6A to 6C, the gate electrode GE may include a work function adjusting material. The work function adjusting material may be a material that is used to adjust a work function of the gate electrode GE. In an embodiment, since the work function adjusting material is injected into the gate electrode GE, the work function of the gate electrode GE may be lowered. In other words, the work function of the gate electrode GE, which is determined by a material (e.g., a conductive material) of the gate electrode GE, may be decreased by the work function adjusting material. In an embodiment, the work function of the gate electrode GE may be lowered as the atomic concentration of the work function adjusting material injected into the gate electrode GE increases. In an embodiment, the work function adjusting material may include at least one of Ph, germanium (Ge), lanthanum (La), aluminum (Al), nitrogen (N), or oxygen (O).

An atomic concentration of the work function adjusting material in each of a lower portion LP and an upper portion UP of the gate electrode GE may be higher than an atomic concentration of the work function adjusting material in a center portion CP of the gate electrode GE. Thus, a work function of each of the lower and upper portions LP and UP of the gate electrode GE may be smaller than a work function of the center portion CP of the gate electrode GE. The lower portion LP may be a portion of the gate electrode GE that is located between a bottom surface Gb of the gate electrode GE and a first level LV1, the first level LV1 being a height in the third direction D3, relative to the upper surface of the substrate 100 as a reference. The upper portion UP may be a portion of the gate electrode GE that is located between a top surface Ga of the gate electrode GE and a second level LV2, the second level LV2 being a height in the third direction D3, relative to the upper surface of the substrate 100. The center portion CP may be a portion of the gate electrode GE that is located between the lower and upper portions LP and UP of the gate electrode GE (e.g., between the first level LV1 and the second level LV2).

In an embodiment, the work function adjusting material in the lower portion LP of the gate electrode GE may be the same as the work function adjusting material in the upper portion UP of the gate electrode GE. In another embodiment, the lower portion LP of the gate electrode GE may include a first work function adjusting material, and the upper portion UP may include a second work function adjusting material different from the first work function adjusting material. Here, the center portion CP of the gate electrode GE may include at least one of the first and second work function adjusting materials.

Referring to FIGS. 6B and 6C, the work function adjusting material in the gate electrode GE may have a lowest concentration Cb in the center portion CP of the gate electrode GE (i.e., between the first level LV1 and the second level LV2), but the inventive concept is not limited to this example. In an embodiment, a portion of the center portion CP of the gate electrode GE may not include the work function adjusting material.

Between the bottom surface Gb of the gate electrode GE and the second level LV2, the work function adjusting material in the gate electrode GE may have a highest concentration Ca between the bottom surface Gb of the gate electrode GE and the first level LV1 (i.e., in the lower portion LP of the gate electrode GE).

An atomic concentration of the work function adjusting material may be decreased abruptly from a level at which the atomic concentration of the work function adjusting material is the highest concentration Ca (i.e., between the bottom surface Gb of the gate electrode GE and the first level LV1) to the first level LV1. The atomic concentration of the work function adjusting material may be decreased gradually from the first level LV1 to a level at which the atomic concentration of the work function adjusting material is the lowest concentration Cb in the center portion CP of the gate electrode GE.

Between the first level LV1 and the top surface Ga of the gate electrode GE, the work function adjusting material in the gate electrode GE may have the highest concentration Ca between the second level LV2 and the top surface Ga of the gate electrode GE (i.e., in the upper portion UP of the gate electrode GE).

The atomic concentration of the work function adjusting material may be increased gradually from a level at which the atomic concentration of the work function adjusting material is the lowest concentration Cb to the second level LV2. The atomic concentration of the work function adjusting material may be increased abruptly from the second level LV2 to a level at which the atomic concentration of the work function adjusting material is the highest concentration Ca (i.e., between the second level LV2 and the top surface Ga of the gate electrode GE).

In the drawings, the highest concentration Ca of the work function adjusting material between the bottom surface Gb of the gate electrode GE and the second level LV2 is illustrated to be equal to the highest concentration Ca of the work function adjusting material between the first level LV1 and the top surface Ga of the gate electrode GE, but the inventive concept is not limited to this example. In an embodiment, the highest concentration Ca of the work function adjusting material between the bottom surface Gb of the gate electrode GE and the second level LV2 may be different from the highest concentration Ca of the work function adjusting material between the first level LV1 and the top surface Ga of the gate electrode GE.

In FIGS. 6B and 6C, the atomic concentration distributions of the work function adjusting material in the gate electrode GE may be different from each other. This difference in the atomic concentration distribution may be caused depending on the kind of the work function adjusting material in the doping process on the gate electrode GE.

Referring to FIG. 6B, between the bottom surface Gb of the gate electrode GE and the first level LV1, the atomic concentration of the work function adjusting material may be increased and then decreased. Between the second level LV2 and the top surface Ga of the gate electrode GE, the atomic concentration of the work function adjusting material may be increased and then decreased.

Referring to FIG. 6C, between the bottom surface Gb of the gate electrode GE and the first level LV1, the atomic concentration of the work function adjusting material may be gradually lowered and then abruptly lowered. Between the second level LV2 and the top surface Ga of the gate electrode GE, the atomic concentration of the work function adjusting material may be abruptly increased and then gradually increased.

The atomic concentration distribution of the work function adjusting material in the gate electrode GE has been described with reference to FIGS. 6B and 6C, but the inventive concept is not limited to this example. The atomic concentration distribution of the work function adjusting material may vary based on the type and method of a subsequent doping process of the work function adjusting material; for example, it may be influenced by the injection energy, the process duration, the type of work function adjusting material, and the injection dose amount, among other factors.

According to an embodiment of the inventive concept, the gate electrode GE may include a work function adjusting material. The atomic concentration of the work function adjusting material in each of the upper and lower portions UP and LP of the gate electrode GE may be higher than an atomic concentration of the work function adjusting material in the center portion CP of the gate electrode GE. Thus, a work function of each of the upper and lower portions UP and LP of the gate electrode GE may be smaller than a work function of the center portion CP of the gate electrode GE. Accordingly, a gate-induced drain leakage current (GIDL) phenomenon, which may occur in the semiconductor pattern SP, may be reduced during the operation of the transistor in the memory cell array 1 (e.g., of FIG. 1) of the semiconductor device. As a result, a failure, which is caused by the GIDL phenomenon, may be reduced, and the reliability of the semiconductor device may be improved.

In addition, since the work function of each of the upper and lower portions UP and LP of the gate electrode GE is smaller than the work function of the center portion CP of the gate electrode GE, opposite end portions of the semiconductor pattern SP may exhibit lower resistance compared to the resistance of the center portion CP of the semiconductor pattern SP. Thus, an amount of on-current flowing through the semiconductor pattern SP may be increased, during the operation of the transistor in the memory cell array 1 (e.g., see FIG. 1) of the semiconductor device. As a result, the electrical characteristics of the semiconductor device may be improved.

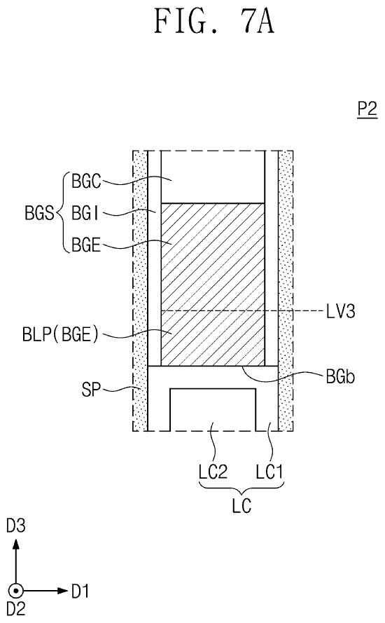

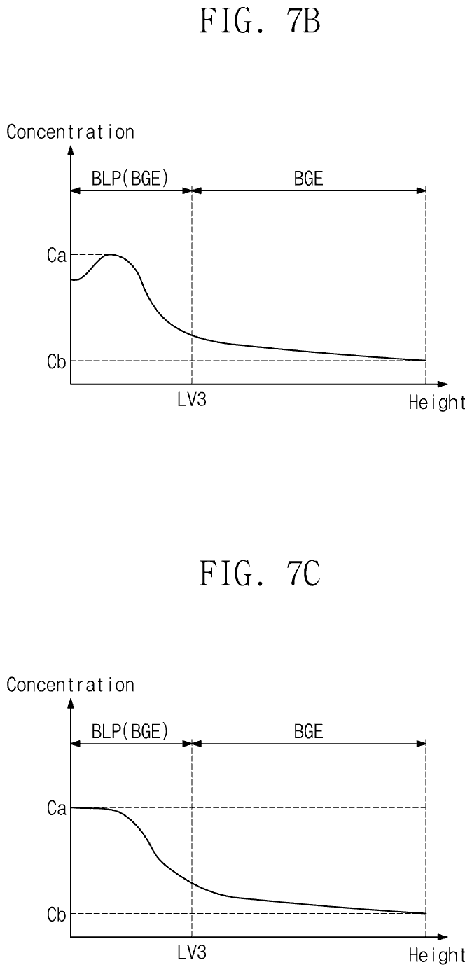

Referring back to FIGS. 4, 5, and 6A, a lower capping pattern LC may be provided on the bottom surface Gb of the gate electrode GE. The lower capping pattern LC may be provided on a bottom surface BGb of a back-gate structure BGS to be described with reference to FIG. 7A. The lower capping pattern LC may be interposed between the bit line BL and the gate electrode GE and between the bit line BL and the back-gate structure BGS. The lower capping pattern LC may be interposed between the lower insulating layer LIL and the gate electrode GE. The lower capping pattern LC may include an insulating material. In an embodiment, the lower capping pattern LC may include at least one of silicon oxide and silicon nitride.

The lower capping pattern LC may include a first lower capping pattern LC1, which is provided to cover the side surface of the semiconductor pattern SP and the bottom surface Gb of the gate electrode GE, and a second lower capping pattern LC2, which is provided between the first lower capping pattern LC1 and the bit line BL. The term “cover” (or “covering,” “covers,” or like terms), as may be used herein, is intended to broadly refer to an element, structure or layer that is on or over another element, structure or layer, either directly or with one or more other intervening elements, structures or layers therebetween.

The first lower capping pattern LC1 may include the work function adjusting material described above. In an embodiment, the work function adjusting material in the first lower capping pattern LC1 may be the first work function adjusting material. In an embodiment, an atomic concentration of the work function adjusting material in the first lower capping pattern LC1 may be higher than an atomic concentration of the work function adjusting material in the center portion CP of the gate electrode GE. In an embodiment, the second lower capping pattern LC2 may not include the work function adjusting material, but the inventive concept is not limited to this example. In another embodiment, if the work function adjusting material in the first lower capping pattern LC1 is diffused into the second lower capping pattern LC2, the second lower capping pattern LC2 may include a work function adjusting material. In this case, the atomic concentration of the work function adjusting material in the first lower capping pattern LC1 may be higher than the atomic concentration of the work function adjusting material in the second lower capping pattern LC2.

An upper capping pattern UC may be provided on the top surface Ga of the gate electrode GE. The upper capping pattern UC may be interposed between the gate electrode GE and an upper insulating layer UIL. A side surface of the upper capping pattern UC may be covered with the gate insulating pattern GI. The upper capping pattern UC may include an insulating material. In an embodiment, the upper capping pattern UC may include at least one of silicon oxide and silicon nitride.

The upper capping pattern UC may include the work function adjusting material described above. In an embodiment, the work function adjusting material in the upper capping pattern UC may be the second work function adjusting material described above. In an embodiment, an atomic concentration of the work function adjusting material in the upper capping pattern UC may be higher than an atomic concentration of the work function adjusting material in the center portion CP of the gate electrode GE.

A cutting pattern CT may be interposed between the word lines WL, which are adjacent to each other in the first direction D1, to separate them from each other. The cutting pattern CT may extend in the third direction D3. In an embodiment, the cutting pattern CT may include an insulating material. In an embodiment, the cutting pattern CT may not include the work function adjusting material, but the inventive concept is not limited to this example. In another embodiment, if the work function adjusting material in the upper capping pattern UC is diffused into the cutting pattern CT, the cutting pattern CT may include a work function adjusting material. Here, the atomic concentration of the work function adjusting material in the upper capping pattern UC may be higher than the atomic concentration of the work function adjusting material in the cutting pattern CT.

The back-gate structure BGS may be provided on a side surface of the semiconductor pattern SP. The back-gate structure BGS may be interposed between the semiconductor patterns SP, which are adjacent to each other in the first direction D1. The back-gate structure BGS and the word line WL may be spaced apart from each other in the first direction D1, with the semiconductor pattern SP interposed therebetween. The back-gate structure BGS may extend in the second direction D2. In an embodiment, a plurality of back-gate structures BGS may be provided. The back-gate structures BGS may be spaced apart from each other in the first direction D1.

Since the back-gate structure BGS is provided, a threshold voltage of a transistor including the semiconductor pattern SP may be controlled by adjusting a voltage applied to the back-gate structure BGS. Thus, adjusting the threshold voltage through the back-gate structure BGS may be easier compared to adjusting the threshold voltage by injecting impurities into the semiconductor pattern SP. Since the threshold voltage is controlled through the back-gate structure BGS, it may be possible to prevent the transistor from being unnecessarily turned on.

The back-gate structure BGS may include a back-gate electrode BGE on the lower capping pattern LC, a back-gate capping pattern BGC on the back-gate electrode BGE, and a back-gate insulating pattern BGI covering side surfaces of them. In an embodiment, the back-gate electrode BGE may be formed of or include at least one of metallic materials (e.g., Ti, Mo, W, Cu, Al, Ta, Ru, Ir, and Co), metal silicide materials (e.g., silicide materials containing Ti, Mo, W, Cu, Al, Ta, Ru, Ir, and Co), or metal nitride materials (e.g., nitride materials containing Ti, Mo, W, Cu, Al, Ta, Ru, Ir, and Co), although embodiments are not limited thereto. In an embodiment, the back-gate capping pattern BGC may include an insulating material. In an embodiment, the back-gate insulating pattern BGI may include at least one of silicon oxide or high-k dielectric materials.

Referring to FIGS. 7A to 7C, the back-gate electrode BGE may include a work function adjusting material. A work function of the back-gate electrode BGE, which is determined by a material (e.g., a conductive material) of the back-gate electrode BGE, may be decreased by the work function adjusting material. In an embodiment, the work function adjusting material in the back-gate electrode BGE may be the same as the work function adjusting material in the lower portion LP of the gate electrode GE.

An atomic concentration of the work function adjusting material in a lower portion BLP of the back-gate electrode BGE may be higher than an atomic concentration of a remaining portion of the back-gate electrode BGE, except for the lower portion BLP. Thus, a work function of the lower portion BLP of the back-gate electrode BGE may be smaller than a work function of the remaining portion of the back-gate electrode BGE. The lower portion BLP may be a portion of the back-gate electrode BGE that is located between a bottom surface BGb of the back-gate electrode BGE and a third level LV3.

Referring to FIGS. 7B and 7C, the work function adjusting material in the back-gate electrode BGE may have the lowest concentration Cb between the third level LV3 and the top surface of the back-gate electrode BGE (i.e., in a remaining portion of the back-gate electrode BGE except for the lower portion BLP of the back-gate electrode BGE), but the inventive concept is not limited to this example. In an embodiment, the remaining portion of the back-gate electrode BGE may not include the work function adjusting material.

Between the bottom surface BGb of the back-gate electrode BGE and the third level LV3, the work function adjusting material in the back-gate electrode BGE may have the highest concentration Ca.

An atomic concentration of the work function adjusting material may be decreased abruptly from a level at which the atomic concentration of the work function adjusting material is the highest concentration Ca to the third level LV3. The atomic concentration of the work function adjusting material may be decreased gradually from the third level LV3 to a level at which the atomic concentration of the work function adjusting material is the lowest concentration Cb.

In FIGS. 7B and 7C, the atomic concentration distributions of the work function adjusting material in the back-gate electrode BGE may be different from each other. As described above, this difference in the atomic concentration distribution may be caused depending on the kind of the work function adjusting material in the doping process on the back-gate electrode BGE.

Referring to FIG. 7B, between the bottom surface BGb and the top surface of the back-gate electrode BGE, the atomic concentration of the work function adjusting material may be increased and then lowered.

Referring to FIG. 7C, between the bottom surface BGb and the top surface of the back-gate electrode BGE, the atomic concentration of the work function adjusting material may be abruptly lowered and then gradually lowered.

The atomic concentration distribution of the work function adjusting material in the back-gate electrode BGE has been described with reference to FIGS. 7B and 7C, but the inventive concept is not limited to this example. The atomic concentration distribution of the work function adjusting material may vary based on the type and method of a subsequent doping process of the work function adjusting material; for example, it may be influenced by the injection energy, the process duration, the type of the work function adjusting material, and the injection dose amount, among other factors.

Referring back to FIGS. 4 and 5, a storage node contact BC may be provided on the semiconductor pattern SP. The storage node contact BC may be provided on a second edge portion EA2 of the semiconductor pattern SP. In an embodiment, the storage node contact BC may be provided on a top surface of the semiconductor pattern SP. The storage node contact BC may include a conductive material. In an embodiment, the storage node contact BC may be formed of or include doped silicon. In an embodiment, a plurality of storage node contacts BC may be provided. The storage node contacts BC may be spaced apart from each other in the first and second directions D1 and D2.

A landing pad LD may be provided on the storage node contact BC. The landing pad LD may be connected to the semiconductor pattern SP through the storage node contact BC. The landing pad LD may include a conductive material. In an embodiment, the landing pad LD may be formed of or include at least one of doped semiconductor materials (e.g., doped silicon and doped germanium), metallic materials (e.g., Ti, Mo, W, Cu, Al, Ta, Ru, Ir, and Co), metal silicide materials (e.g., silicide materials containing Ti, Mo, W, Cu, Al, Ta, Ru, Ir, and Co), or metal nitride materials (e.g., nitride materials containing Ti, Mo, W, Cu, Al, Ta, Ru, Ir, and Co).

In an embodiment, a plurality of landing pads LD may be provided. The landing pads LD may be spaced apart from each other in the first and second directions D1 and D2. In an embodiment, the landing pads LD may be arranged in various shapes (e.g., zigzag, matrix, and/or honeycomb shapes), when viewed in a plan view. In an embodiment, the landing pad LD may have one of circular, elliptical, rectangular, square, rhombic, and hexagonal shapes, when viewed in a plan view.

The upper insulating layer UIL may be provided to surround the storage node contact BC and the landing pad LD. The term “surround” (or “surrounding,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The upper insulating layer UIL may include an insulating material. The upper insulating layer UIL may include a single layer or a composite layer. The upper insulating layer UIL may separate the storage node contacts BC from each other. The upper insulating layer UIL may separate the landing pads LD from each other.

A data storage pattern DSP may be provided on the landing pad LD. The data storage pattern DSP may be connected to the semiconductor pattern SP through the landing pad LD and the storage node contact BC. In an embodiment, a plurality of data storage patterns DSP may be provided. The data storage patterns DSP may be spaced apart from each other in the first and second directions D1 and D2. The data storage pattern DSP may correspond to the data storing element DS described with reference to FIGS. 1 to 3.

In an embodiment, the data storage pattern DSP may be a capacitor including a bottom electrode, a dielectric layer, and a top electrode. In this case, the semiconductor device may be a dynamic random access memory (DRAM) device. In an embodiment, the data storage pattern DSP may include a magnetic tunnel junction pattern. In this case, the semiconductor device may be a magnetic random access memory (MRAM) device. In an embodiment, the data storage pattern DSP may be formed of or include a phase-change material or a variable resistance material. In this case, the semiconductor device may be a phase-change random access memory (PRAM) device or a resistive random access memory (ReRAM) device. However, the inventive concept is not limited to these examples, and the data storage pattern DSP may include various structures and/or materials which can be used to store data.

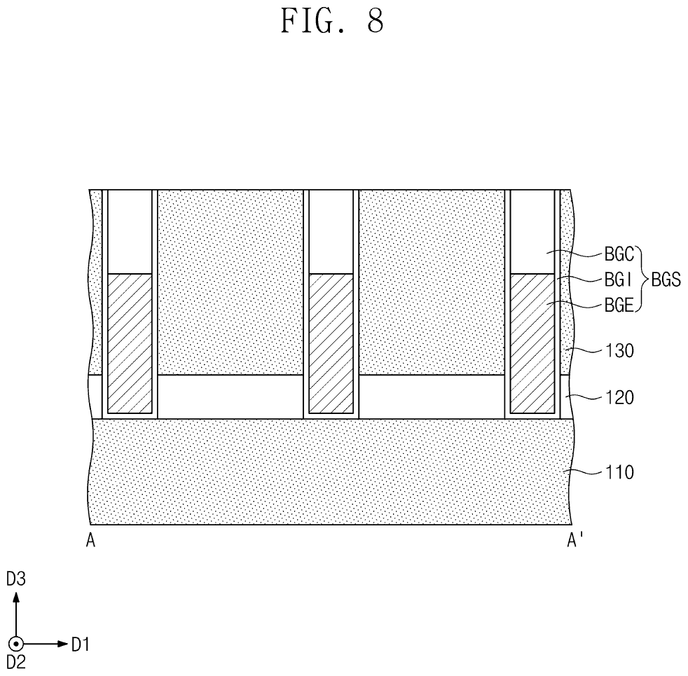

Hereinafter, a method of fabricating a semiconductor device, according to an embodiment of the inventive concept, will be described in more detail with reference to FIGS. 8 to 11. In the following description, a previously-described element may be identified by the same reference number without repeating an overlapping description thereof, for concise description.

FIGS. 8 to 11 are schematic cross-sectional views illustrating intermediate processes in an example method of fabricating a three-dimensional semiconductor device according to an embodiment of the inventive concept. In more detail, FIGS. 8 to 11 may be cross-sectional views taken along line A-A′ of FIG. 4.

Referring to FIGS. 4 and 8, a first substrate 110 may be prepared. A dummy insulating layer 120 and a second substrate 130 may be sequentially formed on the first substrate 110. In an embodiment, the first substrate 110 and the second substrate 130 may include a semiconductor material. The dummy insulating layer 120 may include an insulating material.

Next, a patterning process may be performed on the dummy insulating layer 120 and the second substrate 130. Thus, a portion of each of the dummy insulating layer 120 and the second substrate 130 may be removed. The back-gate structure BGS may be formed in the removed region of each of the dummy insulating layer 120 and the second substrate 130. In an embodiment, the formation of the back-gate structure BGS may include conformally forming the back-gate insulating pattern BGI in the removed region of each of the dummy insulating layer 120 and the second substrate 130 and sequentially forming the back-gate electrode BGE and the back-gate capping pattern BGC on the back-gate insulating pattern BGI. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. Since the back-gate structure BGS is formed, the second substrate 130 may be divided into a plurality of second substrates 130, which are spaced apart from each other in the first direction D1.

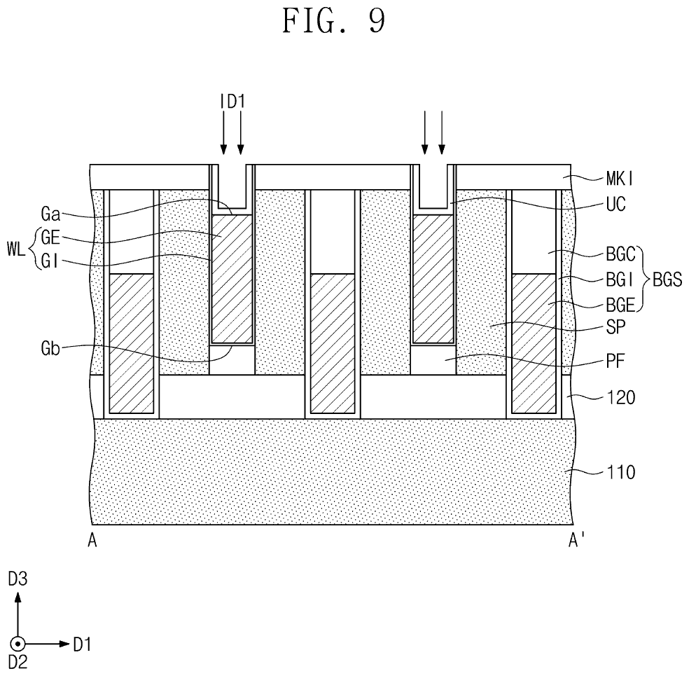

Referring to FIGS. 3 and 9, a first mask pattern MK1 may be formed on the second substrate 130 of FIG. 8 and the back-gate structure BGS. The first mask pattern MK1 may include a plurality of patterns, which are spaced apart from each other in the first direction D1 and extend in the second direction D2.

A removal process using the first mask pattern MK1 as an etch mask may be performed on the third substrate 130 of FIG. 8. Thus, the third substrate 130 of FIG. 8 may be divided into the semiconductor patterns SP, which are spaced apart from each other in the first direction D1. The semiconductor patterns SP may be formed to extend in the third direction D3.

A preliminary filling pattern PF may be formed in a lower portion of an empty space, which is formed by removing a portion of the third substrate 130 of FIG. 8. In an embodiment, the preliminary filling pattern PF may include an insulating material.

The word line WL may be formed on the preliminary filling pattern PF. The word line WL may be formed to extend along the side surface of the semiconductor pattern SP or in the second direction D2. In an embodiment, the formation of the word line WL may include forming the gate insulating pattern GI to conformally cover a remaining portion of the empty space and the top surface of the preliminary filling pattern PF and then forming the gate electrode GE on the gate insulating pattern GI.

Next, the upper capping pattern UC may be formed to conformally cover the gate insulating pattern GI and the exposed top surface Ga of the gate electrode GE.

According to an embodiment of the inventive concept, before a first doping process ID1 to be described below, the upper capping pattern UC may be formed on the gate electrode GE. Thus, it may be possible to minimize an unnecessary damage that may be applied to the gate electrode GE by the first doping process ID1. As a result, the electrical characteristics of the semiconductor device may be improved.

Next, the first doping process ID1 may be performed on an upper portion of the gate electrode GE. The work function adjusting material may be injected into the upper portion of the gate electrode GE through the first doping process ID1. When the first doping process ID1 is performed, the work function adjusting material may be injected into the upper capping pattern UC. In an embodiment, the work function adjusting material may not be injected into elements covered with the first mask pattern MK1, during the first doping process ID1. In an embodiment, the first doping process ID1 may include at least one of an ion implantation process and a gas plasma doping process.

According to an embodiment of the inventive concept, the work function adjusting material may be injected into the upper portion of the gate electrode GE through the first doping process ID1. Thus, an atomic concentration of the work function adjusting material in the upper portion of the gate electrode GE may be higher than an atomic concentration of the center portion CP of the gate electrode GE. As a result, a work function of the upper portion of the gate electrode GE may be smaller than a work function of the center portion CP of the gate electrode GE. Compared to forming the gate electrode GE by repeatedly depositing and etching materials with different work functions, the work function difference between the upper portion and the center portion CP of the gate electrode GE may be more easily adjusted through the first doping process ID1. Thus, the fabrication process of the semiconductor device may be simplified, and the productivity of the semiconductor device may be improved.

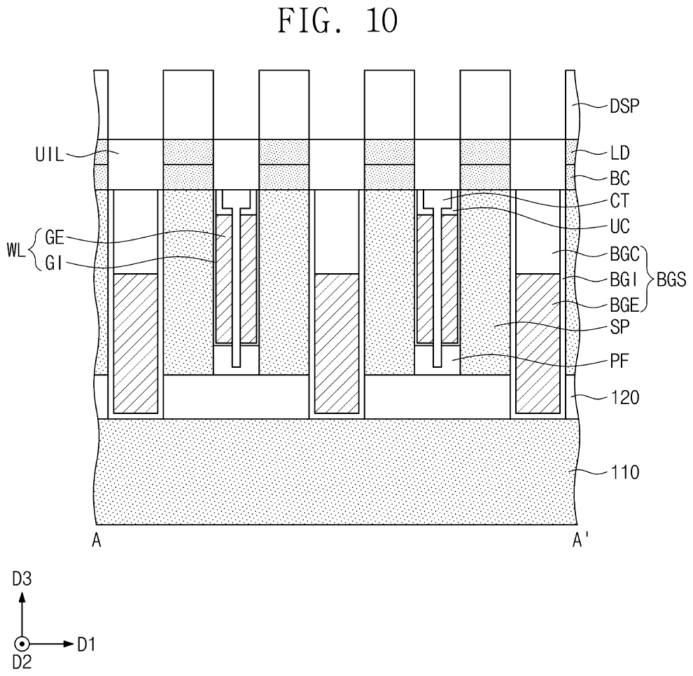

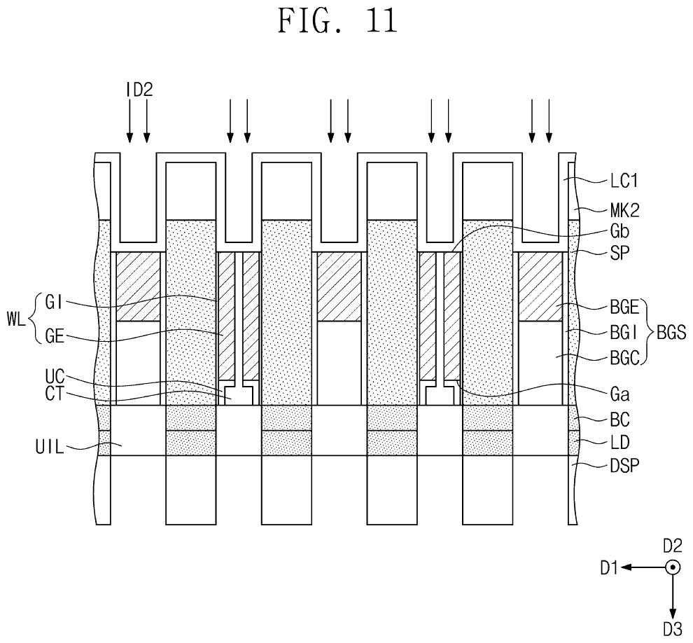

Referring to FIGS. 3 and 10, the first mask pattern MK1 of FIG. 9 may be removed from the first substrate 110. Next, the cutting pattern CT may be formed to cross (i.e., divide) the word line WL in the third direction D3. Thus, each word line WL between adjacent one of the semiconductor patterns SP in the first direction D1 may be divided into a pair of word lines WL, which are spaced apart from each other in the first direction D1.

The storage node contact BC and the landing pad LD may be sequentially formed on the semiconductor pattern SP. The upper insulating layer UIL may be formed to surround each of the storage node contact BC and the landing pad LD. The upper insulating layer UIL may be formed at various times, before or after the formation of the storage node contact BC and the landing pad LD. Next, the data storage pattern DSP may be formed on the landing pad LD.

Referring to FIGS. 3 and 11, the first substrate 110 may be inverted (in the third direction D3). Thus, a bottom surface of the first substrate 110 may be exposed. In the following description of the fabrication method, the terms ‘top surface’ and ‘upper portion’ mean a ‘bottom surface’ and a ‘lower portion’ of the three-dimensional semiconductor memory device described with reference to FIG. 5. Similarly, the terms ‘bottom surface’ and ‘lower portion’ mean a ‘top surface’ and an ‘upper portion’ of the three-dimensional semiconductor memory device described with reference to FIG. 5.

The first substrate 110 of FIG. 10 and the dummy insulating layer 120 of FIG. 10 may be removed. Next, a second mask pattern MK2 may be formed on the semiconductor pattern SP. The second mask pattern MK2 may include a plurality of patterns, which are spaced apart from each other in the first direction D1 and extend in the second direction D2. The second mask pattern MK2 may be vertically overlapped with the semiconductor pattern SP. The second mask pattern MK2 may not be vertically overlapped with each of the word line WL and the back-gate structure BGS. The term “overlapped” (or “overlapping,” or like terms), as may be used herein, is intended to broadly refer to a first element that intersects with at least a portion of a second element in the vertical direction (i.e., third direction D3), but does not require that the first and second elements be completely aligned with one another in a horizontal plane (i.e., first direction D1 and/or second direction D2).

Next, a removal process using the second mask pattern MK2 as an etch mask may be performed on a portion of the back-gate structure BGS, the preliminary filling pattern PF of FIG. 10, and a portion of the gate insulating pattern GI. Thus, the back-gate structure BGS and the top surface Gb of the gate electrode GE (i.e., the bottom surface Gb of the gate electrode GE in FIG. 6A) may be exposed to the outside.

The first lower capping pattern LC1 may be formed to conformally cover the second mask pattern MK2, a portion of the side surface of the semiconductor pattern SP, the exposed top surface of the back-gate structure BGS, and the exposed top surface Gb of the gate electrode GE (i.e., the bottom surface Gb of the gate electrode GE in FIG. 6A).

According to an embodiment of the inventive concept, the first lower capping pattern LC1 may be formed on the gate electrode GE, before a second doping process ID2 to be described below. Thus, it may be possible to minimize an unnecessary damage that may be applied to the gate electrode GE by the second doping process ID2. As a result, the electrical characteristics of the semiconductor device may be improved.

Next, the second doping process ID2 may be performed on each of the upper portion of the gate electrode GE (i.e., the lower portion LP of the gate electrode GE in FIG. 6A) and the upper portion of the back-gate electrode BGE (i.e., the lower portion BLP of the back-gate electrode BGE in FIG. 7A). The work function adjusting material may be injected into each of the upper portion of the gate electrode GE (i.e., the lower portion LP of the gate electrode GE in FIG. 6A) and the upper portion of the back-gate electrode BGE (i.e., the lower portion BLP of the back-gate electrode BGE in FIG. 7A) through the second doping process ID2. During the second doping process ID2, the work function adjusting material may be injected into the first lower capping pattern LC1. During the second doping process ID2, the work function adjusting material may not be injected into the elements covered with the second mask pattern MK2. The work function adjusting material, which is injected through the second doping process ID2, may be the same as or different from the work function adjusting material, which is injected through the first doping process ID1. In an embodiment, the second doping process ID2 may include at least one of an ion implantation process and a gas plasma doping process.

According to an embodiment of the inventive concept, the work function adjusting material may be injected into the upper portion of the gate electrode GE (i.e., the lower portion LP of the gate electrode GE of FIG. 6A) through the second doping process ID2. Thus, the atomic concentration of the work function adjusting material in the upper portion of the gate electrode GE (i.e., the lower portion LP of the gate electrode GE of FIG. 6A) may be higher than the atomic concentration of the center portion CP of the gate electrode GE. As a result, a work function of the upper portion of the gate electrode GE (i.e., the lower portion LP of the gate electrode GE of FIG. 6A) may be smaller than a work function of the center portion CP of the gate electrode GE. Compared to forming the gate electrode GE by repeatedly depositing and etching materials with different work functions, the work function difference between the upper portion (i.e., the lower portion LP in FIG. 6A) and the center portion CP of the gate electrode GE may be more easily adjusted through the second doping process ID2. Thus, the fabrication process of the semiconductor device may be simplified, and the productivity of the semiconductor device may be improved.

Referring back to FIGS. 4 and 5, the second mask pattern MK2 of FIG. 11 and a portion of the first lower capping pattern LC1 may be removed. The second lower capping pattern LC2 may be formed on the first lower capping pattern LC1, and they may constitute the lower capping pattern LC.

The bit line contact DC may be formed on a first edge portion EA1 of the semiconductor pattern SP. The bit line BL may be formed on the bit line contact DC. The lower insulating layer LIL may be formed to cover the bit line contact DC and the bit line BL. The lower insulating layer LIL may be formed at various times, before or after the formation of the bit line contact DC and the bit line BL.

According to an embodiment of the inventive concept, a gate electrode may include a work function adjusting material. An atomic concentration of a work function adjusting material in each of upper and lower portions of the gate electrode may be higher than an atomic concentration of a work function adjusting material in a center portion of the gate electrode. Thus, a work function of each of the upper and lower portions of the gate electrode may be smaller than a work function of the center portion of the gate electrode. Accordingly, a gate-induced leakage current (GIDL) phenomenon in a semiconductor pattern may be reduced during an operation of a transistor in a memory cell array of a semiconductor device. As a result, a failure, which is caused by the GIDL phenomenon, may be reduced, and the reliability of the semiconductor device may be improved.

In addition, since the work function of each of the upper and lower portions of the gate electrode is smaller than the work function of the center portion of the gate electrode, opposite end portions of the semiconductor pattern may have a resistance lower than the center portion of the semiconductor pattern. Thus, an amount of an on-current flowing through the semiconductor pattern may be increased, during the operation of the transistor in the memory cell array of the semiconductor device. As a result, the electrical characteristics of the semiconductor device may be improved.

According to an embodiment of the inventive concept, the work function adjusting material may be injected into the upper and lower portions of the gate electrode through a doping process of injecting the work function adjusting material. Compared to forming the gate electrode by repeatedly depositing and etching materials with different work functions, a work function difference between the upper and lower portions and the center portion of the gate electrode may be more easily adjusted through the doping process. Thus, the fabrication process of the semiconductor device may be simplified, and the productivity of the semiconductor device may be improved.

According to an embodiment of the inventive concept, before the process of injecting the work function adjusting material, an upper capping pattern or a lower capping pattern may be formed on the gate electrode. Thus, it may be possible to minimize an unnecessary damage that may be applied to the gate electrode by the doping process. As a result, the electrical characteristics of the semiconductor device may be improved.

While example embodiments of the inventive concept have been particularly shown and described, it will be understood by one of ordinary skill in the art that variations in form and detail may be made therein without departing from the spirit and scope of the attached claims.

1. A semiconductor device, comprising:
a substrate;
a bit line extending in a first direction parallel to a top surface of the substrate;
a semiconductor pattern on the bit line and extending in a third direction perpendicular to the top surface of the substrate; and
a gate electrode on a side surface of the semiconductor pattern and extending in a second direction parallel to the top surface of the substrate and intersecting the first direction,
wherein the gate electrode comprises a work function adjusting material, and
an atomic concentration of the work function adjusting material in each of lower and upper portions of the gate electrode is higher than an atomic concentration of the work function adjusting material in a center portion of the gate electrode between the lower and upper portions.

2. The semiconductor device of claim 1, wherein a first work function of each of the lower and upper portions of the gate electrode is smaller than a second work function of the center portion of the gate electrode.

3. The semiconductor device of claim 1, wherein the lower, center, and upper portions of the gate electrode form a unitary member.

4. The semiconductor device of claim 1, further comprising a lower capping pattern on a bottom surface of the gate electrode,
wherein the lower capping pattern comprises the work function adjusting material.

5. The semiconductor device of claim 4, wherein the lower capping pattern comprises an insulating material.

6. The semiconductor device of claim 1, further comprising an upper capping pattern on a top surface of the gate electrode,
wherein the upper capping pattern comprises the work function adjusting material.

7. The semiconductor device of claim 6, wherein the upper capping pattern comprises an insulating material.

8. The semiconductor device of claim 1, wherein the work function adjusting material comprises at least one of Ph, germanium (Ge), lanthanum (La), aluminum (Al), nitrogen (N), or oxygen (O).

9. The semiconductor device of claim 1, further comprising a back-gate electrode spaced apart from the gate electrode in the first direction, with the semiconductor pattern therebetween,
wherein a lower portion of the back-gate electrode comprises the work function adjusting material.

10. The semiconductor device of claim 9, wherein a first atomic concentration of the work function adjusting material in the lower portion of the back-gate electrode is higher than a second atomic concentration of the work function adjusting material in a second portion of the back-gate electrode excluding the lower portion of the back-gate electrode.

11. The semiconductor device of claim 9, wherein a first work function of the lower portion of the back-gate electrode is smaller than a second work function of a second portion of the back-gate electrode.

12. The semiconductor device of claim 9, further comprising a lower capping pattern on a bottom surface of the back-gate electrode,
wherein the lower capping pattern comprises the work function adjusting material.

13. The semiconductor device of claim 1, wherein the lower, center, and upper portions of the gate electrode comprise a same conductive material.

14. A semiconductor device, comprising:
a substrate;
a bit line extending in a first direction parallel to a top surface of the substrate;
a semiconductor pattern on the bit line and extending in a third direction perpendicular to the top surface of the substrate; and
a gate electrode on a side surface of the semiconductor pattern and extending in a second direction parallel to the top surface of the substrate and intersecting the first direction,
wherein each of lower and upper portions of the gate electrode comprises a work function adjusting material, and
a first work function of each of the lower and upper portions of the gate electrode is smaller than a second work function of a center portion of the gate electrode between the lower and upper portions of the gate electrode.

15. The semiconductor device of claim 14, wherein the center portion of the gate electrode comprises the work function adjusting material, and
a first atomic concentration of the work function adjusting material in each of the lower and upper portions of the gate electrode is higher than a second atomic concentration of the work function adjusting material in the center portion of the gate electrode.

16. The semiconductor device of claim 14, wherein the lower, center, and upper portions of the gate electrode form a unitary member.

17. The semiconductor device of claim 14, further comprising a lower capping pattern, which is provided on a bottom surface of the gate electrode and includes an insulating material,
wherein the lower capping pattern comprises the work function adjusting material.

18. The semiconductor device of claim 14, further comprising an upper capping pattern on a top surface of the gate electrode and including an insulating material,
wherein the upper capping pattern comprises the work function adjusting material.

19. The semiconductor device of claim 14, further comprising a back-gate electrode spaced apart from the gate electrode in the first direction, with the semiconductor pattern therebetween,
wherein a lower portion of the back-gate electrode comprises the work function adjusting material.

20. A semiconductor device, comprising:
a substrate;
a bit line extending in a first direction parallel to a top surface of the substrate;
a semiconductor pattern on the bit line and extending in a third direction perpendicular to the top surface of the substrate, the semiconductor pattern comprising a first edge portion adjacent to the bit line and a second edge portion opposite to the first edge portion in the first direction;
a bit line contact between the first edge portion of the semiconductor pattern and the bit line;
a gate electrode on a side surface of the semiconductor pattern and extending in a second direction parallel to the top surface of the substrate and intersecting the first direction;
a storage node contact on the second edge portion of the semiconductor pattern;
a landing pad on the storage node contact; and
a data storage pattern on the landing pad,
wherein the gate electrode comprises a work function adjusting material,
a first atomic concentration of the work function adjusting material in each of lower and upper portions of the gate electrode is higher than a second atomic concentration of the work function adjusting material in a center portion of the gate electrode between the lower and upper portions.

21.-27. (canceled)
